(19) United States
(12) Patent Application Publication
(10) Pub. No.: US 2014/0235187 A1
(43) Pub. Date: Aug. 21, 2014

(54) Front-End System for a Radio Transmitter

(71) Applicants: Vrije Universiteit Brussel, Brussel (BE); IMEC VZW, Leuven (BE)

(72) Inventors: Vojkan Vidojkovic, Waalre (NL); Khaled Khalaf, Cairo (EG); Viki Szortyka, Warsawa (PL); Kristof Vaesen, Mortsel (BE); Piet Wambacq, Groot Bijgaarden (BE)

(73) Assignees: Vrije Universiteit Brussel, Brussel (BE); IMEC VZW, Leuven (BE)

(21) Appl. No.: 14/180,393

(22) Filed: Feb. 14, 2014

(30) Foreign Application Priority Data
Feb. 15, 2013 (EP) 13155545.0

(51) Int. Cl. H03F 3/189; H04B 1/04

(52) U.S. Cl. CPC H03F 3/189; H04B 1/04
USPC 455/127.3

(57) ABSTRACT

Front-end systems for a transmitter included in a radio device are disclosed. An example front-end system may comprise a voltage-to-power mixer. The voltage-to-power mixer may be configured to up-convert a baseband signal to a high-frequency signal by multiplying the baseband signal with a local oscillator signal. Additionally, the voltage-to-power mixer may include a voltage feedback circuit. The example front-end system may further comprise a two-stage power amplifier. The two-stage power amplifier may be configured to amplify the high-frequency signal.

### CROSS-REFERENCE TO RELATED APPLICATION

This application claims priority to European Patent Application No. 13155545.0 filed on Feb. 15, 2013, the contents of which are hereby incorporated by reference.

### TECHNICAL FIELD

The present disclosure relates to a front-end system for wireless devices and more specifically for wireless transmitters for mm-wave applications.

### BACKGROUND

For wireless communications at data rates above 1 Gbit/s, a frequency band of 7 GHz has been allocated around 60 GHz. In this frequency band, several applications are targeted with mass-market potential. For example, wireless High Definition Multi-media Interface (HDMI), wireless Universal Serial Bus (USB) and/or SYNC-and-GO, allowing fast data download, are very interesting applications for the consumer market. For wireless consumer products, particularly for battery-operated devices, the key elements are low price and low power consumption. Considering possible implementation technology, complementary metal-oxide semiconductor (CMOS) technology is preferred, as it allows integration of digital and analog blocks on a single chip. Moreover, downscaled digital CMOS technology, which is a cheap technology for large-volume production, is capable of handling 60 GHz signals with baseband bandwidths up to 1 GHz. To relax the link budget (i.e., the gain and the output power of the transmitter), beam-forming, which requires multiple antenna paths at both the receiver side and the transmitter side, is often used. Compact designs occupying small chip areas and consuming low power are essential for beam-forming transceivers operating at 60 GHz.

For a radio transmitter operating at mm-wave frequencies, the most challenging tasks are the design and the implementation of the blocks operating directly at the radio frequency, i.e., so called radio frequency (RF) building blocks. A simplified block diagram of a transmitter that operates at mm-wave frequencies is shown in FIG. 1. The signal to be transmitted is first processed by the baseband (BB) blocks, and then the processed signals (Iᵢₙ, Qᵢₙ) up-converted (e.g., multiplied by Iₗₒ and Qₗₒ from I&Q LO) by the mixers (TXIQmix) from low baseband frequencies to RF frequencies. The I and Q modulated RF signals are summed together to form the modulated RF signal, which is then amplified by the power amplifier (PA) and finally transmitted via the antenna.

The design challenge comes from the fact that the RF building blocks represent the most power-hungry part of a radio transmitter, as they operate directly at mm-wave frequencies. Another challenge in the design at mm-wave frequencies is to provide sufficient gain. Thus, the transmitter front-end main design challenge is the trade-off between power consumption and gain. In addition, the power amplifier and the up-conversion mixer are tuned circuits, which intensively use inductive passive elements (inductors or transformers) to tune out (or cancel) parasitic capacitances. As a result, different resonant circuits are created in the front-end. Accurate prediction of the resonant frequencies and the mutual dependence of these resonant circuits have a key influence on the performance and the robustness of the transmitter's RF building blocks against process spread and modeling inaccuracy.

Different transmitter solutions have been proposed in the art. However, they are primarily focusing on optimal design for only one of the blocks of the transmitter front-end, i.e., the power amplifier. For example, Okada et al. (“A 60 GHz 16QAM/8PSK/QPSK/BPSK Direct-conversion Transceiver for IEEE 802.15.3c”, IEEE ISSCC 2011, pp. 160-161, Feb. 22, 2011) describe a 60 GHz transceiver front-end with a four-stage power amplifier and a conventional current commutating up-conversion mixer, i.e., Gilbert-type mixer. Chan et al. (“A 60 GHz-Band 2×2 Phased-Array Transmitter in 65 nm CMOS”, IEEE ISSCC 2010, pp. 42-43, Feb. 8, 2010), propose a three-stage power amplifier and a conventional Gilbert-type mixer. However, to provide sufficient gain, the power amplifiers are designed with multiple (more than three) cascaded stages, which significantly narrows the bandwidth of the transmitter. As a consequence, e.g., for 60 GHz communication, these solutions cover only two channels of the four available 60 GHz channels. Furthermore, for 60 GHz communication, different modulation schemes, such as binary phase-shift keying (BPSK), quadrature phase-shift keying (QPSK), and quadrature amplitude modulation (QAM) 16, require the power amplifier to operate at different back-offs from its output 1 dB compression point. However, at 1 dB compression, the power amplifier enters a non-linear region of operation, and for non-constant envelope modulations, such as QAM16, the operating point of the power amplifier has to be set several dBs lower than the output 1 dB compression point. In this way, spectral regrowth at the power amplifier output and spectrum mask violations are prevented. In conventional solution, power amplifiers operating in class A are used. The problem is that the efficiency of a power amplifier operating in class A drops significantly when operating at back-off. This degrades the overall efficiency of the transmitter.

### SUMMARY

The present disclosure aims to provide a low-power, low-cost, and area-efficient front-end solution for wireless transmitters operating at mm-wave frequencies.

In one aspect, the present disclosure relates to a front-end system for a radio transmitter comprising: a voltage-to-power mixer arranged for up-converting a baseband signal to a high-frequency signal by multiplying the baseband signal with a local oscillator signal, and a power amplifier arranged for receiving the high-frequency signal and outputting an amplified signal, wherein the mixer is provided with a voltage feedback circuit and the power amplifier comprises a first amplification stage and a second amplification stage. Though the power amplifier comprises two stages, the transmitter provides sufficient gain without any increase in power consumption. Moreover, the reduction of amplification stages leads to a wider transmitter bandwidth response. Additionally, it improves the circuit robustness to variations of parasitic capacitances due to process spread because number of resonant circuits is reduced.

In another embodiment, the voltage feedback circuit of the mixer is provided with a resistive load. The resistive load allows easier control of the mixer gain. Additionally, the feedback may include an amplifier, which increases the feedback loop gain. Advantageously, the proposed mixer allows orthogonalization of its design parameters, which simplifies the mixer's design and implementation procedure and allows for a higher gain.

In other embodiments, matching networks connecting the RF building blocks are implemented using transformers to minimize an occupied chip area and to provide good coupling and a high quality factor. The mixer and the power amplifier are transformer-coupled. Similarly, the first and second amplification stages of the power amplifier are also transformer-coupled. The coupling minimizes the insertion losses and further improves the gain transfer.

In other embodiments, the first and second amplification stages of the power amplifier are each provided with a neutralization circuit comprising a cross-coupled capacitor. The neutralization circuit provides improved amplifier gain and stability. Additionally, the load impedance of the power amplifier is selected such that it allows efficient operation in multi-mode. The power amplifier may operate in class A or class AB, wherein the operation mode may be selected by simply adjusting the bias voltage of the power amplifier. Operation in different classes allows the radio transmitter to operate using different the modulation schemes, such as, for example QPSK, Minimum-Shift Keying (MSK), and/or QAM 16.

Another aspect of the present disclosure relates to a radio device comprising the front-end system as described above.

### BRIEF DESCRIPTION OF THE DRAWINGS

For a better understanding of the present disclosure preferred embodiments are described below in conjunction with the appended figures and figures description, wherein:

FIG. 1 illustrates a block diagram of a conventional transmitter front-end system;

FIG. 2 illustrates a block diagram of a transmitter front-end system, according to one embodiment;

FIG. 3 illustrates a block diagram of a transmitter front-end system, according to an embodiment;

FIG. 4 illustrates a schematic of a power amplifier, according to an embodiment;

FIG. 5 illustrates the difference in power-added efficiency at back-off for an example power amplifier operating in class A and class AB, respectively;

FIG. 6 illustrates, according to an embodiment, the contours for power gain and power output at a 1 dB compression point of an example amplifier operating in class A and class AB, respectively;

FIG. 7 illustrates, according to an embodiment, the contours for drain efficiency of an example amplifier operating in class A and class AB, respectively;

FIG. 8 illustrates a schematic of a mixer, according to an embodiment.

FIG. 9 illustrates a schematic of the amplifier shown in FIG. 8;

FIG. 10 illustrates an RF bandwidth of the transmitted front-end when the power amplifier operates in class A; and

FIG. 11 illustrates an RF bandwidth of the transmitted front-end when the power amplifier operates in class AB.

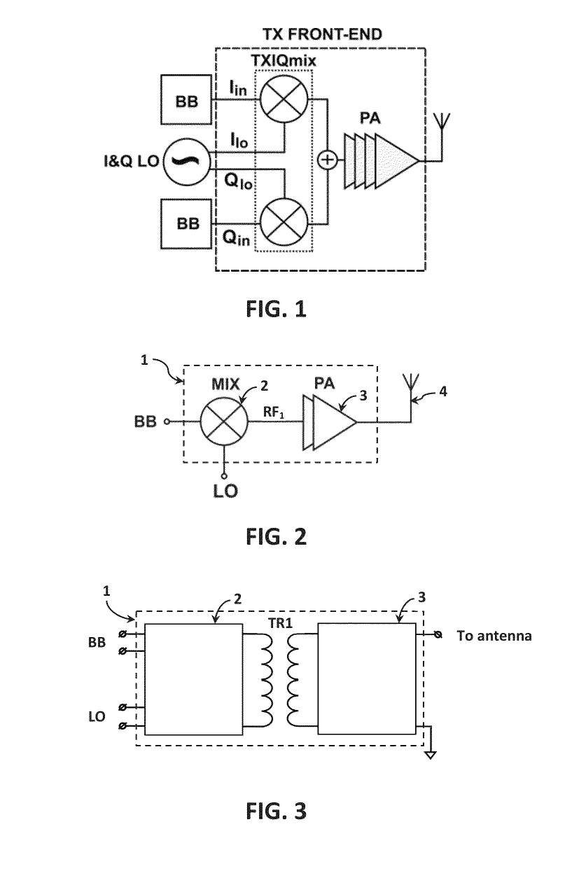

### DETAILED DESCRIPTION

The present invention will be described with respect to particular embodiments and with reference to certain drawings, but the invention is not limited thereto. Some drawings described are schematics and are non-limiting. In the drawings, the size of some of the elements may be exaggerated and/or not drawn on scale for illustrative purposes. The dimensions and/or the relative dimensions do not necessarily correspond to actual reductions to practice of the invention.

Furthermore, the terms first, second, third, and the like in the description and in the claims are used for distinguishing between similar elements and not necessarily for describing a sequential or chronological order. The terms are interchangeable under appropriate circumstances, and the embodiments of the invention can operate in sequences other than the sequences described and/or illustrated herein.

Moreover, the terms top, bottom, over, under, and the like in the description and the claims are used for descriptive purposes and not necessarily for describing relative positions. The terms so used are interchangeable under appropriate circumstances, and the embodiments of the invention described herein can operate in orientations other than the orientations described and/or illustrated herein.

The term “comprising”, as used in the claims, should not be interpreted as being restricted to the means listed thereafter; it does not exclude other elements or steps. It needs to be interpreted as specifying the presence of the stated features, integers, steps, and/or components as referred to, but does not preclude the presence or addition of one or more other features, integers, steps, and/or components, and/or groups, thereof. Thus, the scope of the expression “a device comprising A and B” should not be limited to devices consisting of only components A and B. It means that, with respect to the present invention, the only relevant components of the device are A and B.

In contrast to the prior-art solutions, where it is commonly understood that the mixer is a bad voltage-to-power (or current-to-power) converter, designers try to improve front-end performance by improving the power amplifier (PA), e.g., by adding more amplification stages. Instead, the present disclosure proposes different solutions resulting in modified transmitter front-end systems with improved power consumption, efficiency, and linearity.

FIG. 2 shows a block diagram of a transmitter front-end system 1 comprising a mixer 2 and a two-stage power amplifier 3. The baseband signal BB to be transmitter is first up-converted by the mixer to high-frequency signal RF₁ by multiplying the baseband signal BB with a local oscillator signal LO. The high-frequency signal RF₁ is then amplified by the power amplifier 3 and finally transmitted via the antenna 4. The mixer 2 is a voltage-to-power mixer. To improve a gain of the mixer 2, and its voltage-to-power conversion, without any increase in power consumption, the mixer 2 is provided with a voltage-feedback circuitry. This specific mixer implementation allows orthogonalization of its design parameters, which simplifies the design and implementation procedure of the mixer 2. Additionally, the increase in the gain of the mixer 2 allows for reduction of the amplification stages of the power amplifier 3 to two stages. This directly leads to improved efficiency and to a wider band response of the transmitter. Further, it improves its robustness to variations of parasitic capacitances due to process spread because number of resonant circuits is reduced. For example, for 60 GHz communication, the transmitter is able to cover the complete 7 GHz-wide frequency band, i.e., all four 60 GHz channels.

In particular embodiments, the RF blocks of the transmitter front-end system 1 are transformer coupled to improve the efficiency of the transmitter. As shown in FIG. 3, the mixer 2 and the power amplifier 3 are transformer coupled via a first transformer TR1 to improve the voltage-to-power transfer of the mixer.

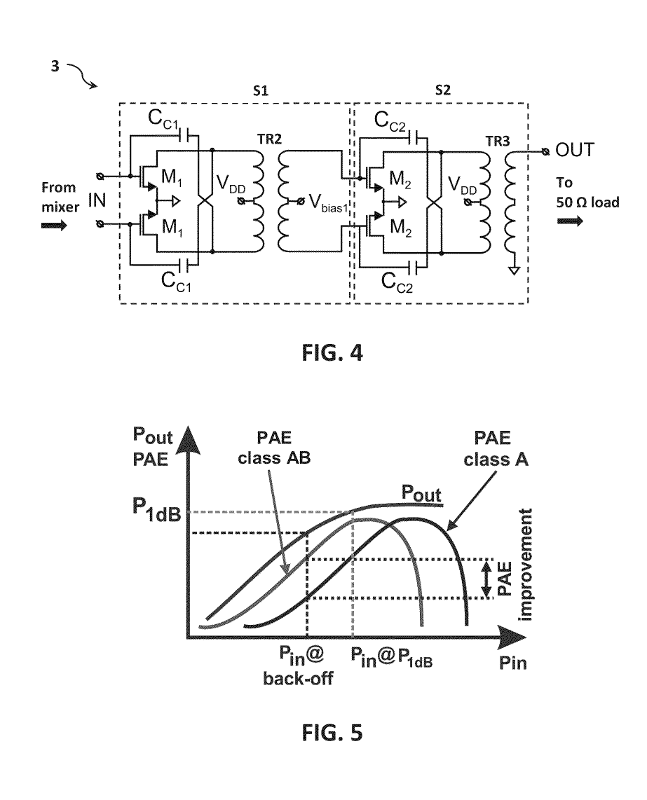

FIG. 4 illustrates a block diagram of the power amplifier 3 consisting of a first amplification stage S1 and a second amplification stage S2, according to another embodiment. Advantageously, to improve the efficiency of the power amplifier 3, the amplification stages S1,S2 are also transformer coupled via a second transformer TR2. In one embodiment, the second transformer TR2 is realized with a turn ration of 2:1. Additionally, the power amplifier 3 is transformer coupled via a third transformer TR3 to the antenna 4.

In other embodiments, each amplification stage S1, S2 of the power amplifier 3 is realized as a pair of differential transistors M₁ (first amplification stage S1), M₂ (second amplification stage S2). Each pair of transistors M₁, M₂ is provided with a neutralization circuit comprising a pair of cross-couple capacitors C_{C1}, C_{C2}, respectively. Each of the cross-coupled capacitors C_{C1}, C_{C2} has a same value as a gate-drain parasitic capacitance of the corresponding transistors M₁, M₂. The advantage of using the differential transistor M₁, M₂ is to improve the robustness to disturbances and gain more power, while the purpose of the cross-coupled capacitors C_{C1}, C_{C2} is to provide neutralization, yielding stability. In contrast to conventional solutions, the power amplifier 3 may operate in multi-mode, which allows efficient operation in different modulation schemes, such as BPSK, QPSK and/or QAM 16. In the different operational modes, the power amplifier 3 can operate efficiently in either class A or class AB.

For the modulation schemes which require low back-off, such as, for example, QPSK, or no back-off at all, such as, for example, MSK, a power amplifier operating in class A is required because it provides high power gain, while for the modulation schemes which require high back-off, such as, for example, QAM 16, a power amplifier operating in class AB is required. A plot showing a dependence of a power-added efficiency PAE on an input signal level (Pᵢₙ) for the power amplifier 3 operating in class A and in class AB is shown in FIG. 5. From this figure, it is clear that the power-added efficiency at a certain back-off is larger when the power amplifier 3 operates in class AB than when the power amplifier 3 operates in class A.

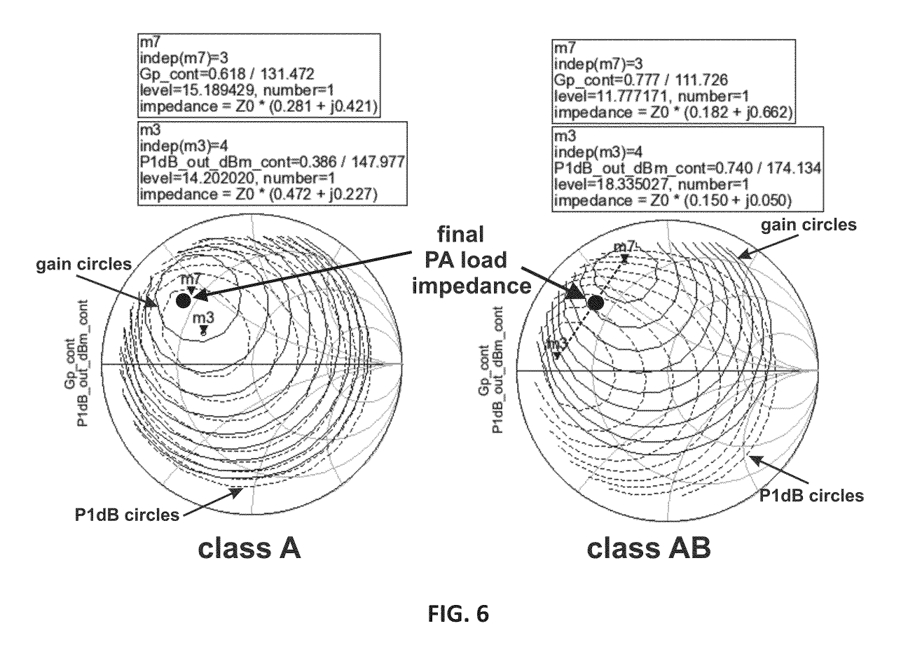

The difficulty in designing an amplifier operating in different modes is explained in more details with reference to FIG. 6. The difficulty is due to the observed trade-off between the load impedance providing the highest 1 dB compression point (P1 dB_out) and the highest power gain (Gp). FIG. 6 illustrates this problem for the second stage S2 of the power amplifier 3, as shown in FIG. 4, with an ideal balun instead of the output transformer TR3 and with conjugate input matching. When an amplifier operates in class AB, the load impedance providing the highest 1 dB compression point (marker m3) and the impedance providing the highest power gain (marker m7) are very distant from each other. The neutralization circuitry, which compensates for the gate-drain parasitic capacitance of the corresponding transistor pair, however, shifts the maximum power gain of the power amplifier 3 when operating in class A from the edge of Smith chart towards the center (markers m3 and m7 are now positioned closer to each other). This shift is also reflected in increase of the stability factor of the amplifier. Surprisingly, it was found that the neutralization circuitry, on the one hand, brings the load impedances providing the highest 1 dB compression point and the highest power gain in class A operation closer together, and on the other hand, positions them roughly in the middle of the trade-off line between the highest 1 dB compression point and the highest power gain in class AB operation. Thus, selecting a load impedance in the middle of the trade-off line between the impedance point yielding highest 1 dB compression point and the highest power gain in class AB operation, which at the same time is very close to the impedance yielding the highest 1 dB compression point and the highest power gain in class A operation, allows the second stage S2, and the power amplifier 3, to operate efficiently in a multi-mode (e.g., as a class A amplifier or a class AB amplifier). The penalty in output power and gain with such selection for the load impedance is acceptable. Moreover, by selecting an appropriate operation mode of the power amplifier 3 based on the required back-off of the modulation scheme, the efficiency of the transmitter is significantly improved. In preferred embodiments, the output load impedance of the power amplifier 3 is selected in the middle of the trade-off line between its highest power gain and its highest output power at the 1 dB compression point. Advantageously, selecting the load impedance as described above allows the selection of the operation mode of the power amplifier 3 to be done by adjusting a bias voltage applied to the gates of the differential transistor pairs M₁, M₂. The adjustment of the bias voltage of only the differential transistor pair M₂ (e.g., the second stage transistors) is also possible. In one embodiment, simple on-chip blocks may be used to perform programmable biasing.

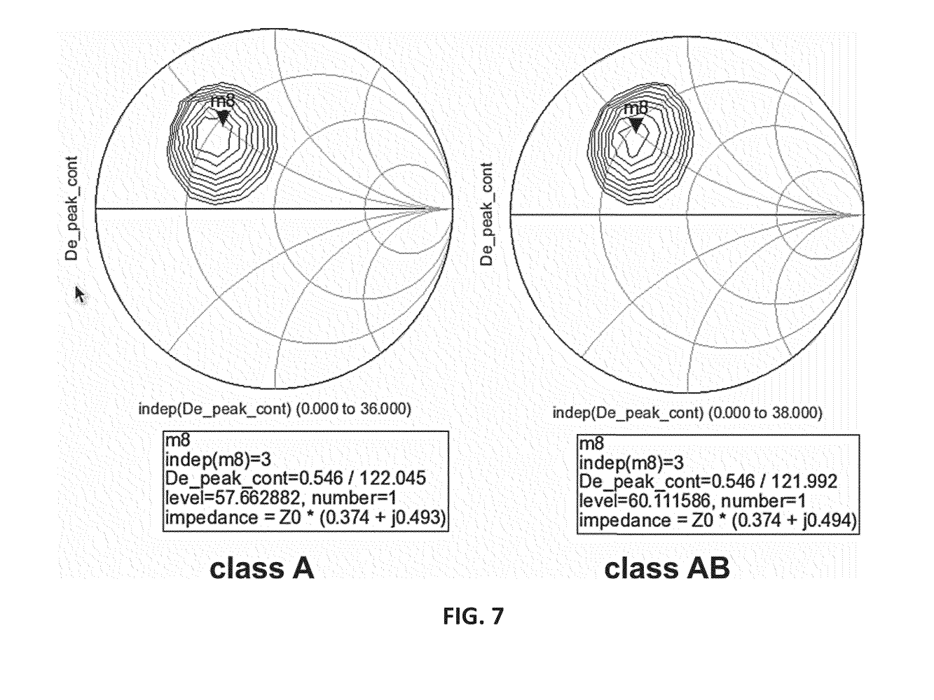

FIG. 7 shows a maximum drain efficiency (DE) of 57.6% and 60.1% reached by a MOS transistor operating at mm-wave frequencies in class A and class AB, respectively. The simulation results show that the 57% drain efficiency for class A operation is higher than the theoretically calculated value of 50%. The reason for obtaining a higher drain efficiency than theoretically predicted is that the theoretical prediction assumes that a perfect sine wave is present at the output of the MOS transistor, while in practice this is not the case due to the nonlinearities of the MOS transistor. The drain efficiency of a MOS transistor operating in class AB is lower than the theoretical prediction for class B of 78.5%. For reaching such high drain efficiency, the MOS transistors have to perform very fast on/off switching. This is possible at low operating frequencies up to 5 GHz, but not at 60 GHz frequencies. At such frequencies, the MOS transistors do not operate in class B, but in class AB, and, as a consequence, the reached drain efficiency is lower, e.g., 60.11%.

In other embodiments, matching networks are used to further improve the efficiency of the transmitter as shown in FIG. 3 and FIG. 4. To minimize occupied chip area and to get better layout compactness, matching networks are implemented using the transformers TR1, TR2, and TR3. In an example of a digital CMOS process with seven metal layers (e.g., copper) and a top aluminum layer, insertion losses can be minimized by implementing higher quality passive components. The geometry of the transformers TR1, TR2, and TR3 may be of an octagonal shape. Additionally, metal stacking through vias for the implementation of transformer windings can be used.

The first transformer TR1 coupling the mixer 2 and the power amplifier 3 and the second transformer TR2 coupling the amplification stages S1, S2 are substantially similar, with a difference being that the first transformer TR1 may be used in one configuration (e.g., a turn ratio of 1:2), while the second transformer TR2 is used in a different configuration (e.g., a turn ration of 2:1). The first transformer TR1 provides very good coupling between the up-conversion mixer 2 and the power amplifier 3, and thus it improves the voltage-to-power transfer of the mixer 2. To improve the quality factor, the transformers TR1,TR2 use lateral coupling, and the windings are implemented using an M7 metal layer connected to an aluminum layer with vias. The quality factor of the primary and secondary windings at 60 GHz are about 15 and about 11 for inductance values of about 150 pH and about 65 pH, respectively. The insertion loss for the case of TR1 at 60 GHz is about 2.3 dB.

Similarly, the transformer TR3, which acts as a load impedance for the second amplification stage S2 of the power amplifier 3, is also designed and optimized for high quality factor and low insertion loss. In one embodiment, the transformer TR3 is implemented with a turn ration of 1:1. The primary winding of the transformer TR3 is implemented with M6 and M7 metal layers connected with vias and a secondary winding using an aluminum layer. At 60 GHz, the quality factor of the primary and secondary windings are 15 and 13, respectively, and the insertion loss is about 1.8 dB.

The insertion losses of these transformers are very low taking into account that a digital CMOS technology with only seven metal layers is used.

As mentioned previously, conventional designs have more than three amplification stages in the power amplifier, which limits the bandwidth response of the transmitter. In the present disclosure, a power amplifier 3 with two stages is proposed. FIG. 4 shows a differential implementation of the two-stage power amplifier 3, according to an embodiment.

Having less power gain in the power amplifier 3 has a negative influence on the output 1 dB compression point of the transmitter front-end system 1. The output 1 dB compression point (P_{1 dB,out,Tx}) can be expressed as:

$$\frac{1}{{P}_{1 dB , out , TX}} = \frac{1}{{P}_{1 dB , out , PA}} + \frac{1}{{P}_{1 dB , out , MIX} {G}_{PA}^{2}} + \frac{1}{{P}_{1 dB , out , BB} {G}_{PA}^{2} {G}_{MIX}^{2}} \qquad ( 1 )$$

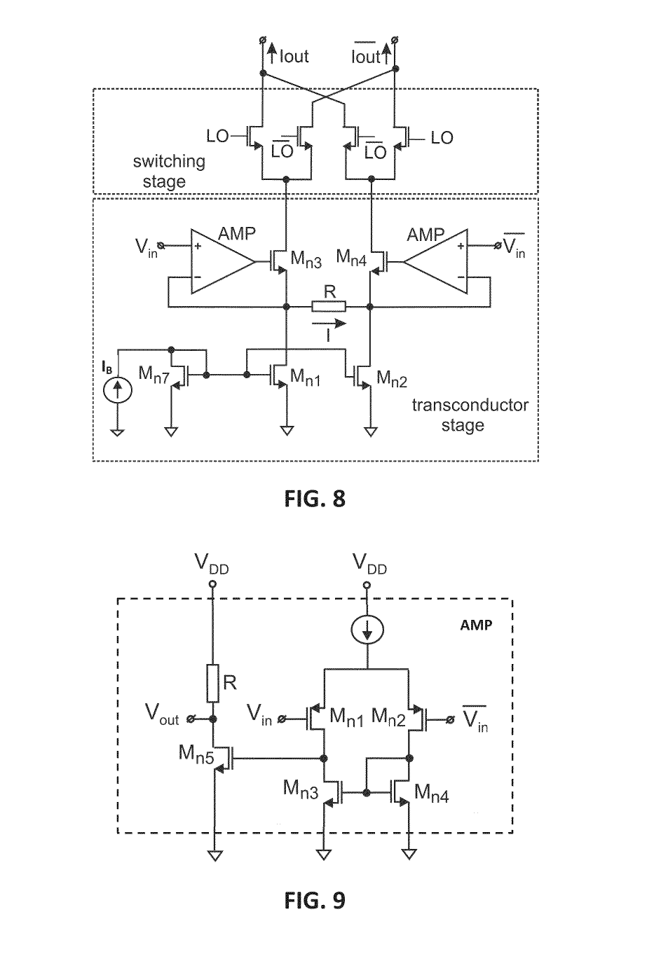

Equation (1) shows that a reduction in the gain of the power amplifier (G_{PA}) deteriorates the overall output 1 dB compression point of the transmitter front-end system 1. To compensate for this reduction in power gain, according to another embodiment, a voltage-to-power mixer provided with a voltage feedback and a resistive load R is proposed, as shown in FIG. 8. To improve the gain of the feedback loop, the voltage feedback may include a feedback amplifier.

Sufficient gain when using a conventional Gilbert cell mixer, however, cannot be achieved without increase in the DC current of the transconductor stage, and, respectively, the overall mixer power consumption. Higher DC current in the transconductor flows into the mixer switches and increases their gate-source voltage. This limits the increase in the gain as the transconductor transistors enter the triode region. With a super-source-follower mixer, this problem is partially solved by introducing a feedback loop which provides some orthogonality between the transconductor gain and its power consumption. This orthogonality is limited, however, by the low value of the loop gain. Additionally, in this architecture, another dependence between the loop gain and the transconductor's DC current is introduced.

By introducing a feedback amplifier AMP in the feedback loops, as shown in FIG. 8, the mixer 2 solves the above issues. High feedback amplifier gain A_{AMP} translates the input voltage Vᵢₙ to the resistor R. This brings the equivalent transconductance equal to 1/R. As the mixer gain is made proportional to 1/R due to the higher loop gain, full orthogonality between the transconductor gain and the transconductor power consumption is achieved. It also introduces orthogonality between the loop gain and the transconductor's DC current due to the independent control of the power consumption of the feedback amplifier AMP. Herein, the loop gain (G_{L}) (looking at half of the mixer circuit) can be approximated as:

$${G}_{L} \approx {A}_{AMP} {gm}_{{M}_{n 3}} \frac{\frac{R}{2}}{1 + {gm}_{{M}_{n 3}} \frac{R}{2}} \qquad ( 2 )$$

wherein, gm_{Mn3} is the transconductance of transistor Mₙ₃ and A_{AMP} is the gain of the feedback amplifier AMP in the feedback of transistor Mₙ₃. The loop gain G_{L} can be increased by increasing the gain A_{AMP} of the amplifier AMP and not the transconductance power consumption.

The mixer 2 has an important advantage because it alleviates the design difficulties by introducing an orthogonality between the mixer gain G_{L} and mixer power consumption, and an orthogonality between the feedback loop gain and the transconductor DC current (mixer power consumption).

The mixer 2 may be designed as follows. First, an ideal feedback amplifier with a large gain (i.e. 60 dB) is selected, with DC current sources replacing Mₙ₁ and Mₙ₂, and transconductor transistors Mₙ₃ and Mₙ₄ sized such that a sufficient transmitter gain and an output 1 dB compression point are obtained. Second, the gain of the feedback amplifier is reduced to a value that does not deteriorate the transmitter gain and output 1 dB compression point. Third, the topology for the feedback amplifier is selected such that it provides required gain and bandwidth.

FIG. 9 illustrates a possible schematic of the feedback amplifier AMP of the mixer 2. It comprises a differential input stage and a common source output stage. As described previously, the feedback amplifier AMP should provide enough bandwidth and sufficient loop gain G_{L} so that the gain of the mixer 2 is kept proportional to 1/R.

Simulation results showing a comparison of the proposed transmitter front-end system 1 with respect to the conventional design proposed by Okada et al. are provided. Table 1 shows a performance comparison of a transmitter front-end system with the power amplifier 3 in combination with (i) a conventional Gilbert-type mixer, (ii) a conventional super-source-follower mixer, and (iii) the mixer 2, respectively. The performance of the transmitter front-end system employing the Gilbert-type mixer is lower compared to the performance of the other two transmitter front-end system configurations. The performance of the transmitter front-end system with the mixer 2 has similar performance to the transmitter front-end system with the super-source-follower mixer. The configuration with the super-source-follower mixer has a higher output 1 dB compression point (P_{1 dB},out,TX), but, at the same time, has a higher power consumption (P_{DC}).

TABLE 1

| | Configuration | | | | | |
|---|---|---|---|---|---|---|
| | Front-end | | Front-end | | Front-end | |
| | system compris- | | system compris- | | system compris- | |
| | ing the power | | ing the power | | ing the power | |
| | amplifier 3 and | | amplifier 3 and | | amplifier 3 and | |
| | a conventional | | a conventional | | a mixer 2 accord- | |
| | Gilbert-cell | | super source- | | ing to present | |
| Performance | mixer | | follower mixer | | disclosure | |
| P_{1 dB}, | 7.9 | dBm | 8.5 | dBm | 8 | dBm |
| out, TX | | | | | | |
| Gain, | 20 | dB | 25 | dB | 25 | dB |
| transmitter | | | | | | |
| P_{DC}, | 37.4 | mW | 37.4 | mW | 29 | mW |
| transmitter | | | | | | |
| mixer | | | | | | |
| P_{DC}, power | 77 | mW | 77 | mW | 77 | mW |
| amplifier | | | | | | |
| P_{DC}, | 114.4 | mW | 114.4 | mW | 106 | mW |
| transmitter | | | | | | |
| front-end | | | | | | |

Table 2 shows the performance of the power amplifier 3 in comparison to the power amplifier of Okada et al. It is clear that the power amplifier 3 reaches a very high maximum power-added efficiency (PAEmax) of 18.7% when it operates in class A mode. At the same time, it provides a 3 dB RF bandwidth of more than 12 GHz. The power amplifier design reported in Okada et al. uses four stages. It achieves a bit higher output 1 dB compression point, but the maximum power-added efficiency is low and it covers only two of the total four 60 GHz channels. This means that the power amplifier design in Okada et al. is a narrow-band design having a 3 dB RF bandwidth of only a couple of GHz. The performance of the power amplifier 3 operating in class AB reaches the highest power-added efficiency at a 5 dB back-off, which is comparable to the other solutions.

TABLE 2

| | Power amplifier | | Power amplifier | | Okada et al. | |
|---|---|---|---|---|---|---|
| | 3 operating | | 3 operating | | PA operating | |
| | in class A | | in class AB | | in class A | |
| Technology | 40 nm LP-CMOS | | 40 nm LP-CMOS | | 65 nm CMOS | |
| Gain | 25 | dB | 19 | dB | 18.3 | dB |
| P_{-1 dB} | 8 | dBm | 7 | dBm | 9.5 | dBm |
| Power amplifier | 18.7% | | 14.8% | | 8.8% | |
| PAEmax | | | | | | |
| Power amplifier | 2.5% | | 4.3% | | 2.5% | |
| PAE @ 5 dB | | | | | | |
| back-off | | | | | | |
| P_{DC}, | 96 | mW | 75.2 | mW | 160.6 | mW |
| transmitter | | | | | | |
| front-end | | | | | | |
| @ 0 dB back-off | | | | | | |
| V_{DD} | 1.1 | V | 1.1 | V | 1.2 | V |

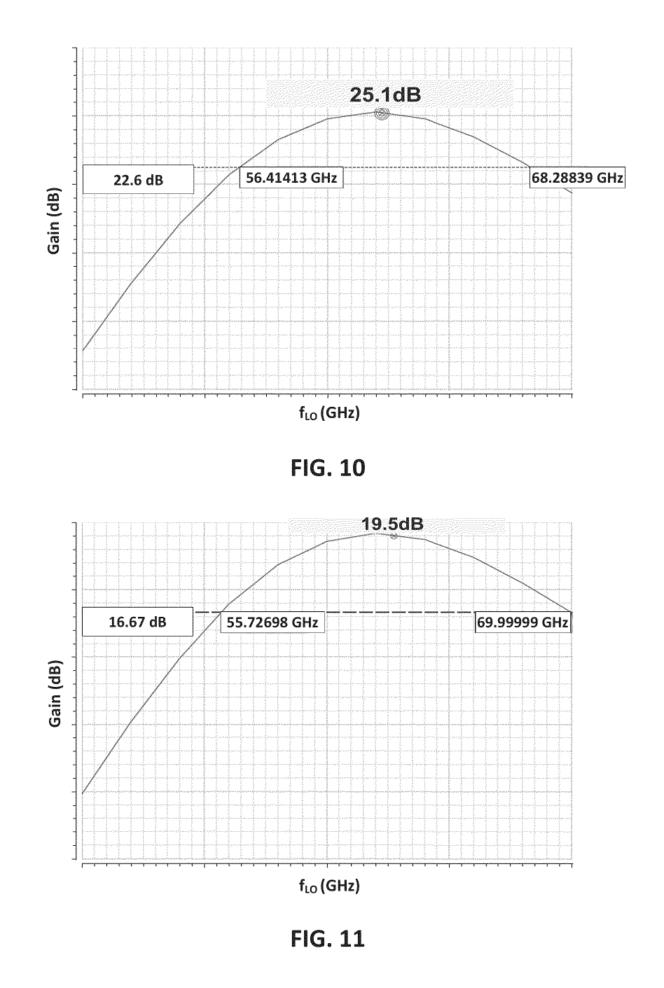

FIG. 10 and FIG. 11 show simulation results of band response of the power amplifier 3 operating in class A and class AB, respectively. The band response at 3 dB below the maximum power gain for both classes is more than 12 GHz wide, i.e., wider than the allocated bandwidth of 7 GHz for 60 GHz communication. For example, the frequency band, which is allocated for 60 GHz communications (57 GHz-65 GHz), falls entirely in the −3 dB RF bandwidth of the transmitter front-end system 1. This leads to a significant improvement of the robustness of the transmitter front-end system 1 to variations of the parasitic capacitances caused by process spread.

The transmitter front-end system 1 achieves high efficiency, maximum power-added efficiency when the power amplifier 3 operates in class A or maximum power-added efficiency at a 5 dB back-off when the power amplifier 3 operates in class AB, while providing very wide −3 dB RF bandwidth of more than 12 GHz. This property of the proposed the transmitter front-end system 1 is unique compared to other conventional architectures.

What is claimed is:

1. A front-end system for a radio frequency transmitter comprising:
a voltage-to-power mixer configured to up-convert a baseband signal to a high-frequency signal by multiplying the baseband signal with a local oscillator signal, wherein the voltage-to-power comprises a voltage feedback circuit; and
a two-stage power amplifier configured to amplify the high-frequency signal.

2. The front-end system of claim 1, wherein the voltage-to-power mixer and the two-stage power amplifier are coupled via a transformer.

3. The front-end system of claim 1, wherein the voltage feedback circuit includes a resistive load.

4. The front-end system of claim 1, wherein the voltage feedback circuit includes an amplifier.

5. The front-end system of claim 1, wherein a first amplification stage of the two-stage power amplifier and a second amplification stage of the two-stage power amplifier are coupled via a transformer.

6. The front-end system of claim 1, further comprising an antenna configured to transmit the amplified high frequency signal, wherein the two-stage power amplifier and the antenna are coupled via a transformer.

7. The front-end system of claim 1, wherein each of a first amplification stage of the two-stage power amplifier and a second amplification stage of the two-stage power amplifier comprises a neutralization circuit that includes a cross-coupled capacitor.

8. The front-end system of claim 1, wherein the power amplifier includes a load impedance configured to allow the two-stage power amplifier to operate in two or more amplifier classes.

9. The front-end system of claim 8, wherein the two-stage power amplifier is further configured to:
operate as a class A amplifier in a first operating mode; and
operate as a class AB amplifier in a second operating mode.

10. The front-end system of claim 8, wherein the two-stage power amplifier is further configured to receive a bias voltage, and wherein an operation mode of the two-stage power amplifier is based on the bias voltage.

11. The front-end system of claim 1, wherein the front-end system is a component of a radio device.
